(19) United States
(12) Patent Application Publication
(10) Pub. No.: US 2026/0276713 A1
(43) Pub. Date: Sep. 17, 2026

(54) METHOD AND APPARATUS FOR DETERMINING STATE OF HEALTH OF A BATTERY

(71) Applicant: O2Micro, Inc., Santa Clara, CA (US)

(72) Inventors: Sterling DU, Palo Alto, CA (US); Heng YANG, Wuhan (CN)

(21) Appl. No.: 19/559,785

(22) Filed: Mar. 6, 2026

(30) Foreign Application Priority Data
Mar. 11, 2025 (CN) 202510286279.2

(51) Int. Cl. G01R 31/367; G01R 31/374; G01R 31/382; G01R 31/392; H01M 10/42

(52) U.S. Cl. CPC G01R 31/367; G01R 31/374; G01R 31/382; G01R 31/392; H01M 10/4285

(57) ABSTRACT

A method for determining a state of health (SOH) of a battery includes: updating, using a processing circuit, a full-charge-capacity (FCC) database based on charging data acquired during a charging process, wherein the FCC database is configured to record battery capacity estimation data corresponding to reference values for a plurality of detected quantities detected in the charging process; and if filling of the FCC database is determined to be completed through the updating, calculating the SOH of the battery based at least on the FCC database.

### RELATED APPLICATION

This application claims benefit under 35 U.S.C. § 119(a) to application No. 202510286279.2, filed with the State Intellectual Property Office of the People's Republic of China on Mar. 11, 2025, which is hereby incorporated by reference in its entirety.

### BACKGROUND

Modern batteries, such as lithium-ion variants, are widely utilized in electric vehicles (EVs), robotics, and energy storage systems due to their longevity, high capacity, and broad operating temperature ranges. Their use is also increasingly expanding into specialized sectors like aviation and aerospace. To ensure operational safety, reliability, and durability, it is essential to monitor battery status accurately and in a timely manner. However, prolonged and frequent use inevitably degrades battery life. Furthermore, improper charging or usage can accelerate aging and potentially lead to safety hazards. Consequently, the precise estimation of a battery's State of Health (SOH) has become a critical factor in ensuring safe operation.

Conventional methods for estimating battery SOH generally fall into two categories: model-based prediction and data-driven prediction. Model-based approaches primarily include electrochemical, equivalent circuit, and empirical degradation models. These methods rely on exploring internal aging mechanisms, which makes it difficult to accurately characterize the capacity degradation process, often resulting in poor predictive robustness and accuracy. In contrast, data-driven methods extract latent SOH information and aging patterns directly from battery test data. By processing vast amounts of charge-discharge data, these methods learn internal dynamics and establish non-linear relationships between raw data and SOH. Among these, Convolutional Neural Networks (CNNs) are frequently used for online SOH estimation due to their strengths in time-series forecasting. However, their standard serial architectures often struggle to capture complex serialized information, leading to poor model generalization and inaccurate SOH estimates.

### SUMMARY

Embodiments according to the present invention provide methods and apparatus for determining state of health (SOH) of a battery based on an FCC database.

In an embodiment, a method for determining an SOH of a battery includes: updating, using a processing circuit, a full-charge-capacity (FCC) database based on charging data acquired during a charging process, wherein the FCC database is configured to record battery capacity estimation data corresponding to reference values for a plurality of detected quantities detected in the charging process; and if filling of the FCC database is determined to be completed through the updating, calculating the SOH of the battery based at least on the FCC database. The updated FCC database can be used to enhance the accuracy of estimating the battery's SOH, increase stability of SOH estimation output, and enhance the user experience.

### BRIEF DESCRIPTION OF THE DRAWINGS

Features and advantages of embodiments of the claimed subject matter will become apparent as the following detailed description proceeds, and upon reference to the drawings, wherein like numerals depict like parts, and in which:

FIG. 1 illustrates a flowchart of an example of a method for determining a battery state of health (SOH), in an embodiment of the present disclosure.

FIG. 2 illustrates a flowchart of an example of a method for determining a battery SOH, in an embodiment of the present disclosure.

FIG. 3 illustrates a flowchart of an example of a method for determining a battery SOH, in an embodiment of the present disclosure.

FIG. 4 illustrates a flowchart of an example of a method for updating a full-charge-capacity (FCC) database based on battery charging data, in an embodiment of the present disclosure.

FIG. 5 illustrates an example of a capacity degradation curve of a battery, recorded by a cycler, according to the prior art.

FIG. 6 illustrates an example of an SOH curve of a battery, determined based on an FCC database, in an embodiment of the present disclosure.

FIG. 7 illustrates a comparison between an SOH curve determined by a cycler, an SOH curve determined based on an FCC database without Kalman filtering, and an SOH curve determined based on the FCC database with Kalman filtering, in an embodiment of the present disclosure.

FIG. 8 illustrates a block diagram of an example of an apparatus configured to determine an SOH of a battery, in an embodiment of the present disclosure.

FIG. 9 illustrates a diagram of an example of a data logical structure of an FCC database, in an embodiment of the present disclosure.

### DETAILED DESCRIPTION

Reference will now be made in detail to the various embodiments of the present disclosure, examples of which are illustrated in the accompanying drawings. While described in conjunction with these embodiments, they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

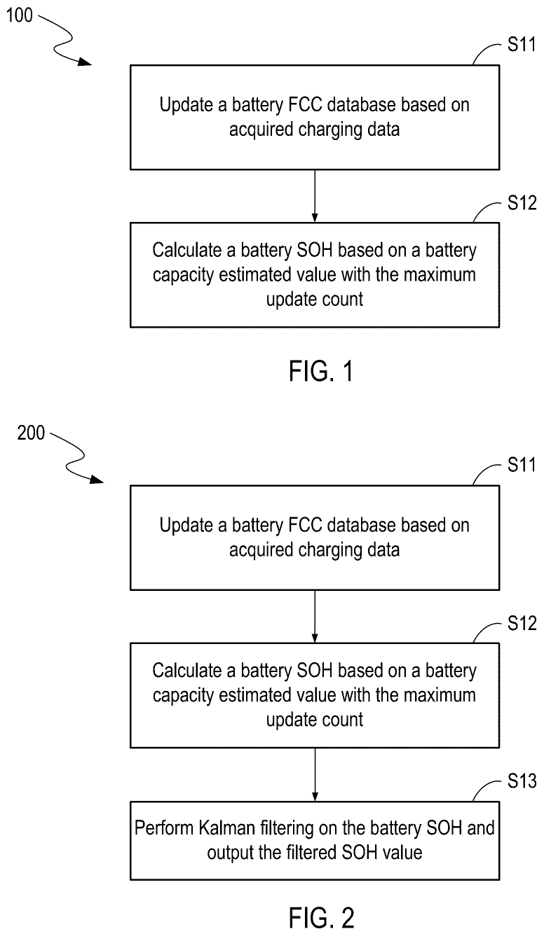

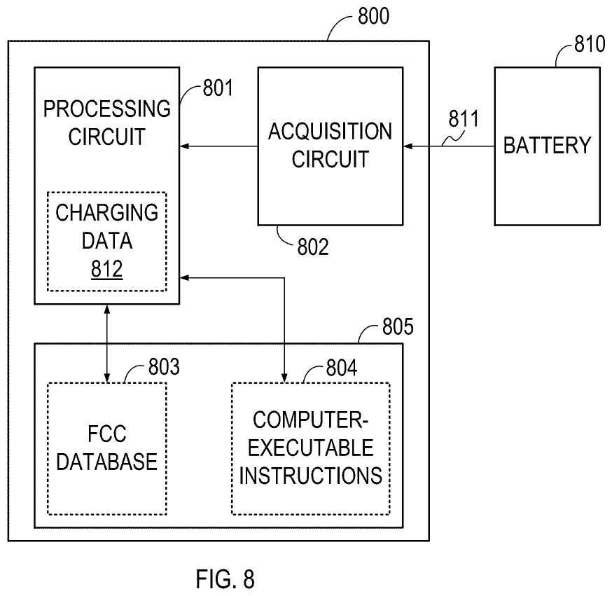

It should be borne in mind, however, that all of these and similar terms are to be associated with the appropriate physical quantities and are merely convenient labels applied to these quantities. Unless specifically stated otherwise as apparent from the following discussions, throughout the present disclosure, discussions utilizing terms such as “updating,” “filling,” “recording,” “determining,” “identifying,” “performing,” “calculating,” “acquiring,” or the like, may refer to actions and processes of and executed by an apparatus or computer system (e.g., the apparatus or system 800 in FIG. 8) or similar electronic computing device or processor (e.g., the actions or processes of the methods of FIGS. 1, 2, 3, and 4). A computer system or similar electronic computing device manipulates and transforms data represented as physical (electronic) quantities within memories, registers or other such information storage, transmission or display devices. In its most basic configuration, a computer system or the like includes at least one processing unit and memory. The computer system may also have additional features and/or functionality, such as the capability for communicating with other devices, the capability to receive user inputs, and the capability to display results.

Embodiments described herein may be discussed in the general context of computer-executable instructions residing on some form of computer-readable storage medium, such as modules, executed by one or more computers, other devices, or circuits. By way of example, and not limitation, computer-readable storage media may comprise non-transitory computer storage media and communication media. Generally, modules may include software, routines, programs, objects, components, data structures, etc., that perform particular tasks or implement particular abstract data types. The functionality of the modules may be combined or distributed as desired in various embodiments. Modules may also be implemented using circuits such as an acquisition circuit or a processing circuit (e.g., a chip or a processor). Moreover, the modules are merely logical modules defined based on specific functions implemented by the modules and are not intended to limit an implementation. For example, a module may be implemented by one or more application-specific integrated circuits, software programs, or a combination thereof.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory (e.g., an SSD) or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media may embody computer-executable instructions, data structures, and modules, and includes any information delivery media. By way of example, and not limitation, communication media may include wired media such as a wired network or direct-wired connection, and wireless media such as acoustic, radio frequency (RF), infrared and other wireless media. Combinations of any of the above can also be included within the scope of computer-readable media.

As used herein, a parameter or the like may be the name of a property or metric (e.g., state of charge, full charge capacity, current, temperature, etc.) or the numerical value of that property or metric. A person of ordinary skill in the art will understand how the term is being used based on its context. The term “present” or “current” may be used to refer to the point in time when, for example, a property or metric is measured or determined (e.g., calculated or otherwise obtained).

### Method and Apparatus for Determining State of Health of a Battery

As discussed in the background above, battery safety is a critical concern, as failures can lead to fires or explosions. Battery safety is closely managed by monitoring the battery's state of health (SOH), which reflects its degradation level. Embodiments according to the presently disclosed invention are integrated into a practical application of accurately and efficiently evaluating SOH. More specifically, these embodiments improve the accuracy of the SOH value while also improving the performance of a battery-powered electronic device (specifically, the computing/processing circuitry used by the device to calculate the SOH; e.g., see FIG. 8) by reducing the computational resources consumed during the SOH calculation, thereby also reducing the amount of power (electricity) used by the device to perform the SOH calculation. Reducing power consumption is an important consideration in battery-powered electronic devices. The ranges of values of the parameters used to calculate SOH, and the various combinations of those parameters and their values, can complicate the calculation of SOH; therefore, accurate, quick, and efficient calculations of SOH is beyond the capability of a human and relies on the use of a computing system or the like (e.g., FIG. 8), particularly considering the time constraints associated with determining SOH in real time.

In the present disclosure, “update” or “updating” refers to filling data into a data space that has not yet been populated, or refreshing data in a data space that already contains data. In some embodiments, “update” (or “updating”) may also be referred to as “fill” (or “filling”).

In the present disclosure, “completed filling,” “completion of filling,” or the like can refer to a state where the number of times a data entry has been updated exceeds a predetermined threshold. In some embodiments, the number of times a parameter (e.g., a data entry or a value) was updated can be referred to as the “update count” of the parameter.

In the present disclosure, full-charge-capacity (FCC) data of a battery includes an initial battery capacity value and an estimated battery capacity value. The “initial battery capacity value” refers to the full charge capacity of a battery when it is new (e.g., when its SOH value is 100%). The “estimated battery capacity value” refers to an estimated value of the full charge capacity after the battery has been in use for a period of time. The “initial battery capacity value” may be known—for example, a default or design value provided by a battery manufacturer—or it may be unknown. Regardless of whether the “initial battery capacity value” is known or unknown, according to the methods in some embodiments of the present disclosure, it may be updated once or a few times during the early stage of battery use and not updated thereafter. In contrast, the “estimated battery capacity value” may be updated multiple times throughout the entire lifecycle of the battery.

In some embodiments, the state and environment of the battery (e.g., including charging current, battery temperature, etc.) may affect the battery capacity value, thereby influencing the battery health value. Therefore, an embodiment of the present disclosure provides an FCC database. The FCC database can be used to describe battery capacity values under specific conditions (e.g., under specific charging currents and battery temperatures).

In some embodiments, the FCC battery database includes multiple data points, each corresponding to one or more battery capacity values under a specific condition of different conditions (e.g., different charging currents and different temperatures). If the update count of a data point in the FCC database exceeds a specific threshold, and the battery capacity values at that data point are greater than zero, then the FCC database can be considered/determined to have completed filling—that is, the filling of the FCC database is complete.

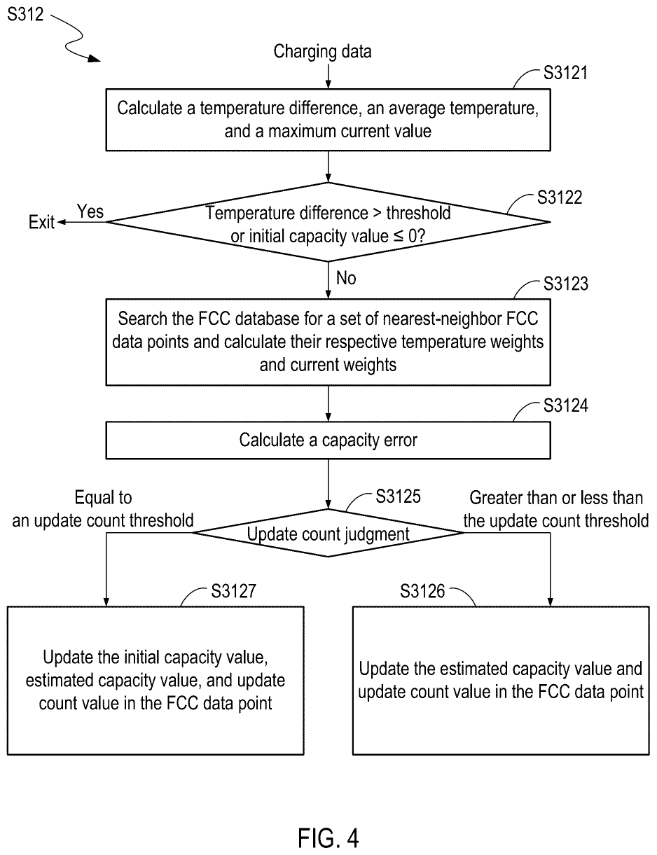

In some embodiments, the system may periodically (e.g., daily, weekly, monthly, etc.) determine whether to update the FCC database. Examples of the criteria used to make this determination are provided below (for instance, see step S3122 of FIG. 4). In some other embodiments, the determination of whether to update the FCC database can be made under specific circumstances. For example, the system may check if an update is needed whenever the battery experienced a full charge cycle or an equivalent full charge cycle (or a predetermined number of cycles such as two or three). An equivalent full charge cycle (EFC) represents the total usage of a battery's capacity, calculated by adding up partial charge/discharge cycles until they total 100% of the battery's capacity.

In some embodiments, a charging process of a battery may include an initial charging stage, a constant-current charging stage, and a constant-voltage charging stage. In the initial charging stage, the battery power is low, and the charging current is set to a smaller value to protect the battery. In the constant-current charging stage, the battery power is within a normal range, and the charging current may be set to a larger value. In the constant-voltage charging stage, the battery enters or is about to enter a charge termination state, and the charging current is gradually reduced until the battery is fully charged. Therefore, the charging current in the constant-current charging stage may be considered the maximum charging current of the battery during that charging process. Accordingly, the “maximum current” mentioned in the present disclosure may refer to the charging current of the battery during the constant-current charging stage.

### First Method Embodiment

An embodiment of the present disclosure includes a method for determining a battery SOH, which employs an adaptive fusion strategy to increase the precision of SOH estimation.

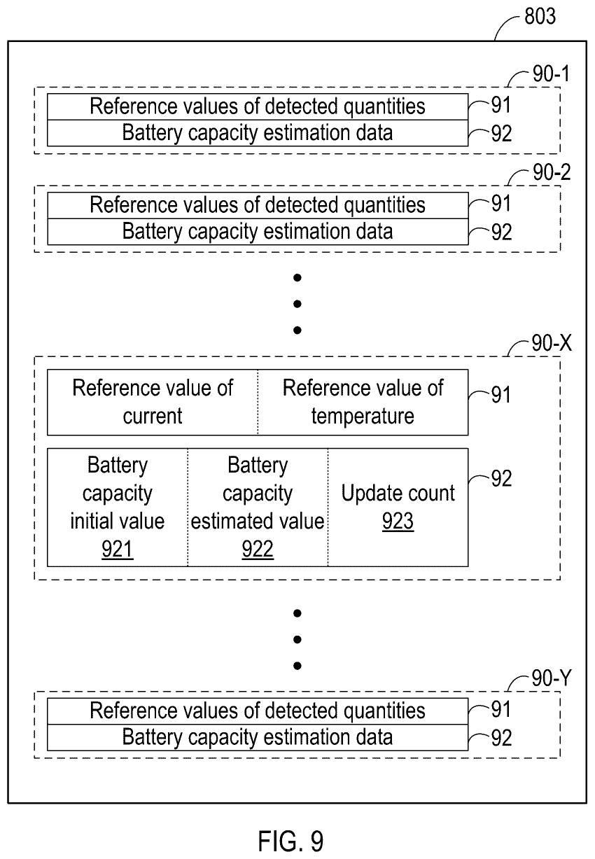

FIG. 1 illustrates a flowchart of an example of a method 100 for determining a battery SOH, in an embodiment of the present disclosure. FIG. 8 illustrates a block diagram of an example of an apparatus 800 configured to determine an SOH of a battery 810, in an embodiment of the present disclosure. FIG. 9 illustrates a diagram of an example of a data logical structure of an FCC database 803, in an embodiment of the present disclosure. FIG. 1 is described in combination with FIG. 8 and FIG. 9. In some embodiments, a processing circuit, e.g., 801 in FIG. 8, is configured to perform the method 100.

The method 100 in the example of FIG. 1 includes steps S11 and S12. In step S11, the processing circuit 801 updates an FCC database 803 based on charging data 812 acquired during a charging process of the battery 810. The FCC database 803 is configured to record battery capacity estimation data 92 (e.g., see FIG. 9) corresponding to reference values 91 for a group of detected quantities 811 (e.g., including temperature and current) detected in the charging process of the battery 810. Step S12 includes calculating the SOH of the battery 810 based at least on the FCC database 803 if filling of the FCC database 803 is determined to be completed through the updating. In an embodiment, the SOH of the battery is 810 is calculated based at least on the FCC database 803 in response to filling of said FCC database being determined to be completed through said updating.

In this first method embodiment, by using the battery charging data 812 to update the FCC database 803 that records the battery capacity estimation data 92, data for various factors affecting the battery SOH (data for factors such as temperature, current, depth of discharge, operating conditions, etc.) are recorded at multiple times and fused, which effectively improves the accuracy of battery SOH estimation. Data fusing methodologies and algorithms are known in the art. The various factors may each be represented as a combination or set of multiple parameters of the battery, including, e.g., temperature, current, impedance, and the like.

During a charging process of the battery 810, the apparatus 800 in FIG. 8 can collect/acquire charging data 812 and perform various processing operations on the collected/acquired charging data 812. The charging data 812 can include one or more detectable parameters in the charging process. The detectable parameters can include a maximum temperature value, a minimum temperature value, a maximum current value, a minimum current value, impedance, a battery voltage value, a coulombic accumulation amount, a state of charge (SOC) at the beginning of the charging process, an SOC at the end of the charging process, battery energy density, and an estimated charge amount fcc_est_{c} for a present charging cycle.

A more detailed description of steps S11 and S12 is presented below.

In step S11, the processing circuit 801 updates the FCC database 803 based on the acquired charging data 812. The FCC database 803 is configured to record battery capacity estimation data 92 under the condition of different sets of reference values 91 for the detected quantities 811. For example, battery capacity estimation data 92 corresponding to a set of reference values 91 for the detected quantities 811 includes an initial battery capacity value 921, an estimated battery capacity value 922, and an update count 923, associated with the set of reference values 91.

For example, as shown in FIG. 9, the FCC database 803 includes data points 90-1 to 90-Y (Y is a natural number), where each data point 90-X (X=1, 2, . . . , Y) is configured to record battery capacity estimation data 92 in association with a respective set of reference values 91. In other words, when a charging cycle of the battery 810 is complete, if the detected quantities 811 of the battery 810, determined in the charging cycle, have values equal to a set of reference values 91 of a data point in the FCC database 803, then the battery capacity estimation data 92 of that data point can represent a charge capacity of the battery 810 in the charging cycle.

In some embodiments, the battery 810 is monitored using Q different types of measurements (Q is a natural number). These measurements form a Q-dimensional grid. Along each axis of the grid, specific values are set at regular intervals. By combining these specific values, the system creates a collection of distinct scenarios, e.g., sets of reference values 91, that make up the database.

As an illustrative and non-limiting example, a set of reference values 91 may include a reference value of a first detected quantity and a reference value of a second detected quantity, e.g., Q=2. Accordingly, the FCC database 803 includes multiple instances of battery capacity estimation data 92, each of which is associated with respective reference values of the first and second detected quantities. In this example, the FCC database 803 can be referred to as a two-dimensional (2D) FCC database. Each of the battery capacity estimation data 92 and its corresponding reference values 91 of the first and second detected quantities can form a data point. In some embodiments, e.g., as shown in FIG. 9, the first detected quantity may include current, and the second detected quantity may include temperature. The reference values 91 of the first and second detected quantities may include a current reference value and a temperature reference value.

In some embodiments, when the FCC database 803 is initially constructed, the aforementioned data points 90-1 to 90-Y may be assigned initial values using data provided by, for example, the battery manufacturer and then updated in subsequent steps, or they may all be assigned a value of zero. Although not shown in FIG. 1, the method 100 may further include steps for constructing and initializing the FCC database 803.

In an example of step S11, the processing circuit 801 can determine a value of each detected quantity (e.g., a real-time value) in a group of detected quantities 811 based on charging data 812 acquired in a charging process of the battery 810. Based on a comparison between the values of detected quantity (e.g., real-time values) and corresponding reference values 91 (e.g., stored values), the processing circuit 801 can perform multi-dimensional linear interpolation on the battery capacity estimation data 92 to determine a cumulative capacity value CP_{CM}. Based on the cumulative capacity value CP_{CM} and an estimated charge amount fcc_est_{c} derived from the charging data 812, the processing circuit 801 can update the battery capacity estimation data 92 associated with the corresponding reference values 91. The process of performing multi-dimensional linear interpolation on the battery capacity estimation data 92 to determine the cumulative capacity value CP_{CM} can include: identifying, for each detected quantity 811, one or more reference values 91 that are nearest neighbors to the value of that detected quantity 811; determining a weight WGT for the battery capacity estimation data 92 corresponding to each identified reference value 91 based on a difference between the value of each detected quantity 811 and its one or more nearest-neighbor reference values 91; and calculating a weighted sum of an estimated battery capacity value 922 in the battery capacity estimation data 92 corresponding to the reference values 91, based on the weight WGT. The weighted sum can serve as the cumulative capacity value CP_{CM}.

By way of example, the nearest-neighbor reference values can include the closest reference value less than the detected quantity's value and/or the closest reference value greater than or equal to the detected quantity's value, in a specific measurement dimension. For example, the detected quantity can be a current, and the detected quantity's value can be 5.3 Amps. If there are reference points at 5.0 Amps and 6.0 Amps with no other reference points in between, then the nearest neighbors are identified as these two reference points. 5.0 Amps and 6.0 Amps. Additionally, weights assigned to parameter values (e.g., in the battery capacity estimation data 92) associated with the two reference points (e.g., 5.0 Amps and 6.0 Amps) are determined based on a difference between the detected quantity's value (e.g., 5.3 Amps) and each of the two reference values. More specifically, a weight assigned to the parameter value associated with a reference value (e.g., 5.0 Amps) closer to the detected quantity's value (e.g., 5.3 Amps) is larger than a weight assigned to the parameter associated with another reference value (e.g., 6.0 Amps).

In an embodiment, the battery capacity estimation data 92 is updated using the determined cumulative capacity value CP_{CM}. For example, a capacity error value fcc_error is calculated by determining the difference between the estimated charge amount fcc_est_{c}, derived from the charging data 812, and the cumulative capacity value CP_{CM}. For each set of references values 91 including the nearest neighbors of the detected quantities 811, its corresponding estimated battery capacity value 922 is updated based on the capacity error value fcc_error and the calculated weight WGT. Specifically, the estimated battery capacity value 922 corresponding to the nearest-neighbor reference values 91 is corrected using the capacity error value fcc_error. The weight WGT defines the degree of this correction. For instance, the capacity error value fcc_error is multiplied by the weight WGT, and the resulting weighted error is added to the original estimated battery capacity value 922 to perform the update. The update count 923 of the estimated battery capacity value 922 is also updated, e.g., incremented by one. In some embodiments, the update count 923 of the estimated battery capacity value 922 can be incremented by one each time the estimated battery capacity value 922 is updated/corrected.

In some embodiments, the estimated charge amount fcc_est_{c} derived from the charging data 812 is calculated based on a cumulative coulombic charge CC during charging and a remaining capacity at the beginning of charging. The calculated charge amount fcc_est_{c} may be further adjusted using a capacity correction value associated with a termination current (e.g., also referred to as “end-of-charge current”). For example, the estimated charge amount fcc_est_{c} may be calculated as the sum of the cumulative coulombic charge CC, the remaining capacity, and the capacity correction value. This is not a restrictive definition; the estimated charge amount fcc_est_{c} can be determined from the charging data 812 using any suitable method.

In step S12, when the filling of the FCC database 803 is determined to be completed, the processing circuit 801 can search the FCC database 803 for a data point having the highest update count 923, calculate the battery SOH as the ratio of the estimated battery capacity value 922 to the initial battery capacity value 921 at that data point, and output the ratio as the final SOH. In some embodiments, if the FCC database 803 includes a data point that has been updated for a number of times (e.g., referred to as “update count”), the update count exceeds a predetermined threshold (e.g., ten), and the values 921 and 922 at that data point are greater than zero, then the filling of the FCC database 803 is determined to be completed.

Additionally, step S12 can include: if the filling of the FCC database 803 is determined to be not yet complete, the processing circuit 801 continues to fill the database. In this scenario, the processing circuit 801 can calculate the battery SOH based on a predetermined aging factor (e.g., represented by dropratio) of a battery health value and the number of charging cycles (e.g., represented by chg_cycle_cnt) the battery 810 experienced, and output the calculated value as the final SOH of the battery 810.

Moreover, during the process of updating the estimated battery capacity value 92, the initial battery capacity value 921 is selectively updated, in some embodiments. For example, the initial battery capacity value 921 may be updated only once when the update count 923 reaches a preset threshold, e.g., five, ten, or twenty. For another example, the initial battery capacity value 921 may be updated a few times until the update count 923 reaches a preset threshold. Note that these updates to the initial capacity value 921 are intended solely to improve its initial accuracy; it will not be updated further in subsequent calculations to ensure the stability of the SOH calculation baseline.

Accordingly, the method 100 in the example of FIG. 1 updates the FCC database 803 in real-time based on the charging data 812, enabling a more accurate and adaptive estimation of battery SOH. This method is applicable across a wide temperature range, requires low computational overhead, and provides high stability.

### Second Method Embodiment

The following describes a second method embodiment of the present disclosure. As a variation of the first method embodiment, in addition to the steps described therein, this embodiment further includes step S13 following step S12 (see FIG. 2). Step S13 includes: performing Kalman filtering on the calculated battery SOH, and using the filtered SOH as the final battery SOH. FIG. 2 illustrates a flowchart of an example of a method 200 for determining a battery SOH, in an embodiment of the present disclosure. FIG. 2 is described in combination with FIG. 1, FIG. 8, and FIG. 9. In some embodiments, the processing circuit 801 is configured to perform the method 200.

In an embodiment of the Kalman filtering, the system noise and measurement noise in the Kalman filter equations are dynamically adjusted based on temperature to construct a state equation and an observation equation, wherein:
the state equation is given by: sohₖ=sohₖ₋₁−dropratio/10+w; and
(1) the observation equation is given by: sohₖ=soh_{f}+v,
(2) where sohₖ represents the battery SOH at the k^{th} iteration; sohₖ₋₁ represents the battery SOH at the (k−1)^{th} iteration; soh_{f} represents the battery SOH estimate calculated based on the FCC database 803; dropratio represents the aging factor of the battery health value; w represents the system noise; and v represents the measurement noise.

Specifically, the calculation result from the state equation (1) serves as a “predicted value,” while the soh_{f} derived from the FCC database 803 in the observation equation (2) serves as a “measured value.” The final filtered SOH is an optimal estimate obtained by fusing these predicted and measured values through weighted calculation. By incorporating Kalman filtering, the system can effectively suppress unnatural fluctuations, such as the SOH increasing or dropping abruptly, thereby reducing output noise caused by extreme temperatures and ensuring stability without compromising estimation accuracy.

Those of ordinary skill in the art may adjust the Kalman filtering method and related parameters according to the method 200 described in this embodiment. Such adjustments do not depart from the inventive concept of the present disclosure and are therefore considered to fall within the requested scope of protection.

### Third Method Embodiment

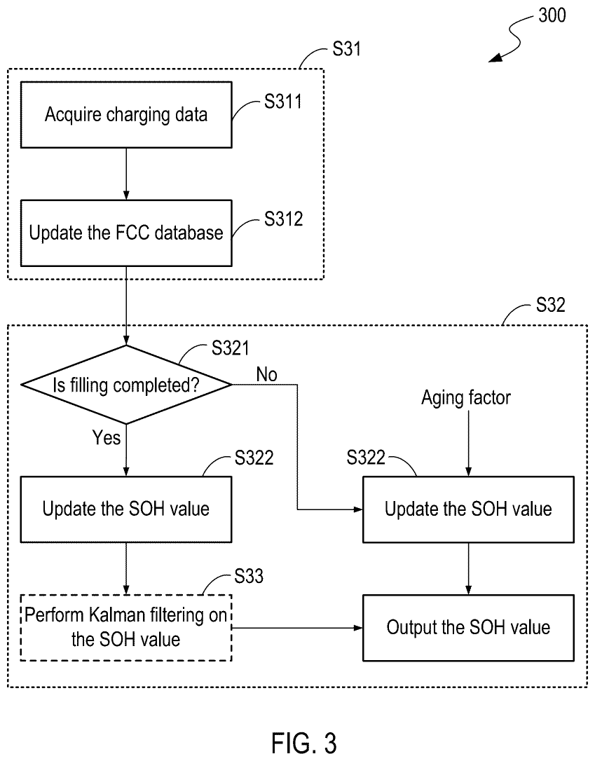

The following describes a third method embodiment of the present disclosure with reference to FIG. 3 and FIG. 4. This embodiment provides a more detailed introduction to the method for determining battery SOH, using current and temperature as an exemplary group of detected quantities 811.

FIG. 3 illustrates a flowchart of an example of a method 300 for determining a battery SOH, in an embodiment of the present disclosure. FIG. 3 is described in combination with FIG. 1, FIG. 2, FIG. 8, and FIG. 9. In some embodiments, the processing circuit 801 is configured to perform the method 300. As shown in FIG. 3, the method 300 includes step S31 and step S32.

In step S31, the processing circuit 801 updates or fills the FCC database 803 based on the charging data 812 acquired during a charging process. In step S32, the processing circuit 801 determines whether the FCC database 803 has completed filling. If filling is complete, the battery SOH is calculated based at least on the FCC database 803. If filling is not yet complete, the battery SOH is calculated based on the aging factor dropratio and the number of charging cycles chg_cycle_cnt.

In the example of FIG. 3, step S31 includes sub-steps S311 and S312. In step S311, the charging data 812 is collected/acquired. In step S312, the FCC database 803 is updated based on the charging data 812.

More specifically, step S311 includes acquiring the charging data 812, e.g., using the acquisition circuit 802 in FIG. 8, and processing the data, e.g., using the processing circuit 801, to determine various parameters. These parameters may include the maximum and minimum temperature values, maximum and minimum current values, battery impedance, cumulative coulombic charge CC, state of charge (SOC) at the start and end of charging, and estimated charge amount fcc_est_{c}, for a present charging cycle.

In some embodiments, current and temperature are used as the group of detected quantities 811; therefore, the FCC database 803 can be a two-dimensional (2D) database. The reference values in the 2D FCC database 803 can include current reference values and temperature reference values. For instance, the current reference value may correspond to a maximum current curr_{MAX} of the battery 810 (e.g., maximum charging current or constant-current charging current) in a charging cycle, while the temperature reference value may correspond to an average temperature tempₐᵥₑᵣ of the battery 810 in the charging cycle. In an embodiment, the average temperature may be the mean of multiple temperature values recorded between the maximum and minimum temperatures in the charging data 812.

In some embodiments, step S311 further includes constructing a 2D array of different temperature points (e.g., temperature reference values) and current points (e.g., current reference values) to serve as the FCC database 803. For purposes of illustration and not limitation, in an embodiment, the FCC database 803 is an N×M array, where N represents the number of temperature reference values and M represents the number of current reference values. For example, there may be four temperature points (e.g., 5° C., 20° C., 40° C., 65° C.) and three current points (e.g., 2A, 5A, 10A). The battery capacity estimation data 92 corresponding to each combination 91 of temperature and current points includes an initial battery capacity value 921, an estimated battery capacity value 922, and an update count 923. Initialization may be completed by setting the initial values of the initial battery capacity value 921, estimated battery capacity value 922, and update count 923 to zero.

Following step S311, the processing circuit 801 can perform step S312. Examples of sub-steps of step S312 are illustrated in FIG. 4, according to an embodiment of the present disclosure. FIG. 4 is described in combination with FIG. 1, FIG. 2, FIG. 3, FIG. 8, and FIG. 9. In the example of FIG. 4, step S312 includes sub-steps S3121 through S3127.

Step S3121 includes calculating a temperature difference and an average temperature tempₐᵥₑᵣ based on temperature values from the charging data 812. For example, the temperature difference can be the difference between the maximum and minimum temperature values. The average temperature may be the mean of multiple temperature values recorded between the maximum and minimum temperatures in the charging data 812.

In step S3122, if the absolute value of the temperature difference exceeds a temperature threshold temp_th (e.g., 20° C.), or if the estimated charge amount fcc_est_{c} from the charging data 812 is less than or equal to zero, then the update of the FCC database 803 is terminated; otherwise, the process proceeds to step S3123.

Step S3123 involves identifying nearest-neighbor data points in the FCC database 803 (e.g., four data points of points 90-1 to 90-Y in FIG. 9) and calculating their corresponding temperature and current weights. More specifically, in an embodiment, the processing circuit 801 identifies the two temperature points, temp₀ and temp₁, that are closest to the average temperature tempₐᵥₑᵣ, as well as the two current points, curr₀ and curr₁, closest to the maximum current curr_{MAX}. In an embodiment, the temperature points (e.g., temperature reference values) recorded in the FCC database 803 include a maximum temperature value (e.g., 65° C.) and a minimum temperature value (e.g., 5° C.), and the current points (current reference values) include a maximum current value (e.g., 10A) and a minimum current value (e.g., 2A). If the average temperature tempₐᵥₑᵣ is greater than the maximum temperature value, then the temperature points temp₀ and temp₁ are set to the maximum temperature value. If the average temperature tempₐᵥₑᵣ is less than the minimum temperature value, then the temperature points temp₀ and temp₁ are set to the minimum temperature value. Similarly, if the current curr_{MAX} is greater than the maximum current value, then the current points curr₀ and curr₁ are set to the maximum current value. If the current curr_{MAX} is less than the minimum current value, then the current points curr₀ and curr₁ are set to the minimum current value.

The weights for these reference points are determined based on their proximity to the values of the detected quantities 811. In cases where the value of a detected quantity lands exactly on a boundary or reference point, the weights are distributed equally. For example, if temp₀=temp₁, then their respective temperature weights temp_weight₀ and temp_weight₁ are set to temp_weight₀=temp_weight₁=0.5*Coeff1, where Coeff1 is a coefficient and can be set to be 1000. Similarly, if curr₀=curr₁, then their respective curent weights curr_weight₀ and curr_weight₁ are set to curr_weight₀=curr_weight₁=0.5*Coeff2, where Coeff2 is a coefficient and can be set to be 1000. In all other cases, the formulas for calculating the temperature and current weights for the nearest-neighbor data points are as follows for this example:

$${temp\_weight}_{0} = [ ( {temp}_{1} - {temp}_{over} ) / ( {temp}_{1} - {temp}_{0} ) ] * Coeff 1 ; \qquad ( 3 )$$

$${temp\_weight}_{1} = Coeff 1 - {temp\_weight}_{0} ; \qquad ( 4 )$$

$${curr\_weight}_{0} = [ ( {curr}_{1} - {curr}_{MAX} ) / ( {curr}_{1} - {curr}_{0} ) ] * Coeff 2 ; and \qquad ( 5 )$$

$${curr\_weight}_{1} = Coeff 2 - {curr\_weight}_{0} . \qquad ( 6 )$$

Step S3124 involves calculating a capacity error value fcc_error. First, a cumulative capacity value CP_{CM} is determined by performing a weighted accumulation using multi-dimensional linear interpolation. This is done by multiplying the temperature weights temp_weight₀ and temp_weight₁, the current weights curr_weight₀ and curr_weight₁, and estimated battery capacity values fcc_est_{tempi,currj} of the nearest-neighbor data points, as shown below:

$${CP}_{CM} = \frac{1}{Coeff 1 * Coeff 2} {\sum }_{i = 0}^{1} {\sum }_{j = 0}^{1} {temp\_weight}_{i} * {curr\_weight}_{j} * {fcc\_est}_{{temp}_{i} , {curr}_{j} .} \qquad ( 7 )$$

The capacity error value fcc_error is determined by subtracting the cumulative capacity value CP_{CM} from the estimated charge amount fcc_est_{c} derived from the charging data 812, as shown below:

$$fcc\_error = {fcc\_est}_{c} - \frac{1}{Coeff 1 * Coeff 2} {\sum }_{i = 0}^{1} {\sum }_{j = 0}^{1} {temp\_weight}_{i} * {curr\_weight}_{j} * {fcc\_est}_{{temp}_{i} , {curr}_{j} .} \qquad ( 8 )$$

where fcc_est_{c} represents the estimated charge amount derived from the charging data 812.

In an embodiment, the estimated charge amount fcc_est_{c} is calculated as the sum of a cumulative coulombic charge in a charging process, a remaining capacity at the beginning of the charging process, and a capacity correction value associated with a termination current (or an end-of-charge current), as shown below:

$${fcc\_est}_{c} = CC + \frac{fcc * start\_dodsoc}{Coeff 3} + ( save\_min \_current - eocma ) / 10 , \qquad ( 9 )$$

where, CC represents a cumulative coulombic charge;

$$\frac{fcc * start\_dodsoc}{Coeff 3}$$

represents a remaining capacity of the battery 810 at the beginning of the charging process; start_dodsoc represents an SOC of the battery 810 at the beginning of charging; Coeff3 is a coefficient and can be set to be 10000; (save_min_current-eocma)/10 represents a capacity correction value associated with a termination current (e.g., a “tail capacity” estimated via current curve fitting); save_min_current represents the minimum charging current recorded during the charging process, and eocma represents the termination current. In embodiments, a charging process includes a constant-current charging stage followed by a constant-voltage charging stage. During the constant-voltage charging stage, when the charging current drops to the termination current, the corresponding SOC is equivalent to 100%, and the charging cycle is complete.

In equations (7) and (8), the variables temp_weightᵢ, curr_weightⱼ, and fcc_est_{tempi,currj} represent the temperature weight, current weight, and estimated battery capacity value, respectively, for each of the four nearest-neighbor data points in the FCC database 803 in this example, where each of i and j is 0 or 1 (e.g., i, j∈{0, 1}).

Step S3125 involves evaluating the respective update count 923 recorded for each of the abovementioned nearest-neighbor data points (e.g., for such data points) in sequence, e.g., one by one. Based on the evaluation results, the battery capacity estimation data 92 for these data points are updated accordingly. Specifically, if the update count 923 of an FCC data point (e.g., hereinafter, data point XX) of the FCC data points (e.g., four such data points) is greater than or less than a first preset threshold update_th1 (e.g., 10), then the data point XX is updated in step S3126; otherwise, the data point XX is updated in step S3127. In step S3126, the estimated battery capacity value 922 at the data point XX is updated, the update count 923 is incremented by one, and the initial battery capacity value 921 remains unchanged. The estimated battery capacity value fcc_est_{tempi,currj} is updated according to the following formula:

$${fcc\_est}_{{temp}_{i} , {curr}_{j}} = {fcc\_est}_{{temp}_{i} , {curr}_{j}} + \frac{1}{Coeff 1 * Coeff 2} * fcc\_error * {temp\_weight}_{i} * {curr\_weight}_{j} . \qquad ( 10 )$$

If it is determined in Step S3125 that the update count 923 of the data point XX is equal to the first preset threshold update_th1, then the data point XX is updated in step S3127. In step S3127, both the estimated battery capacity value 922 and the initial battery capacity value 921 at the data point XX are updated, and the update count 923 is incremented by one. In step S3127, the method for updating the estimated battery capacity value 922 is similar to that used in step S3126. The initial battery capacity value 921 is updated to the present estimated battery capacity fcc_est_{tempi,currj}.

In the abovementioned embodiment, the data point XX is updated in step S3127 only when the update count 923 of the data point XX is equal to the first preset threshold update_th1. However, the invention is not so limited. In alternative embodiments, the data point XX can be updated in step S3127 as long as the update count 923 is less than or equal to the first preset threshold update_th1.

Accordingly, each of the nearest-neighbor data points (e.g., four such data points) individually undergoes the evaluation in step S3125 and is updated in the corresponding step S3126 or step S3127.

Referring to FIG. 3, following step S31, the process proceeds to step S32. In an embodiment, step S32 involves calculating the battery SOH based on the ratio of the estimated battery capacity value 922 to the initial battery capacity value 921 from the battery capacity estimation data 92 that has the highest update count. In the example of FIG. 3, step S32 includes sub-steps S321, S322 and S323. In some embodiments, step S32 may also include step S33.

In step S321, the processing circuit 801 traverses the FCC database 803 to identify the battery capacity estimation data 92 having the highest update count 923 and evaluates this count. If the highest update count 923 exceeds a second preset threshold update_th2, and both the initial battery capacity value 921 and the estimated battery capacity value 922 are greater than zero, then the filling of the FCC database 803 is considered/determined to be completed, and the process proceeds to step S322; otherwise, the FCC database 803 is considered “incomplete,” and the process proceeds to step S323. Note that the second preset threshold update_th2 is greater than or equal to the aforementioned first preset threshold update_th1.

In step S322, the processing circuit 801 calculates sohr using the ratio of the estimated battery capacity value 922 to the initial battery capacity value 921 (associated with the highest update count 923), as shown below:

$${soh}_{f} = Coeff 3 * \frac{fcc\_est}{fcc\_init} , \qquad ( 11 )$$

where, fcc_est represents the estimated battery capacity value 922, and fcc_init represents the initial battery capacity value 921.

In some embodiments, the resulting value of sohs is output as the final battery SOH. In some other embodiments, as mentioned above, step S32 can also include step S33. Step S33 involves performing Kalman filtering on a calculated SOH estimate (e.g., the sohs calculated in step S322). The filtered SOH value is then used as the final output of the battery SOH. The specific method and equations (such as the state equation and observation equation) for this Kalman filtering are similar to those described in Step S13, wherein the sohs calculated in step S322 serves as the measured value in the Kalman filter equations. Detailed implementation of the Kalman filtering is not repeated here.

In step S321, if the update count 923 recorded in the most-updated battery capacity estimation data 92 is less than or equal to the second preset threshold update_th2, or if the recorded initial battery capacity value 921 and/or estimated battery capacity value 922 are zero, the processing circuit 801 determines that the FCC database 803 has not completed filling and proceeds to step S323.

Step S323 involves calculating the number of battery charging cycles and determining the battery health value soh_{d} based on a battery aging factor, which is then output as the final battery SOH. The calculation is as follows:

$${soh}_{d} = Coeff 3 - chg\_cycle \_cnt * dropratio / 10 , \qquad ( 12 )$$

where chg_cycle_cnt represents the number of battery charging cycles, and dropratio represents the aging factor of the battery health value. For example, based on empirical data, if the battery health decreases by 3% after 100 charging cycles, the dropratio would be set to 30.

The method 300 described in this third method embodiment is exemplary and not restrictive. Its various steps may be combined with, supplement, or replace the method steps described in the first and second method embodiments. Any technical solution formed by such combinations falls within the scope of the present application. Furthermore, the numerical values provided in certain steps are for illustrative purposes only and should not be construed as limitations on the methods described in this disclosure.

### Effects

The performance of the method for estimating SOH using an FCC database, e.g., 803, according to the present disclosure was verified. The entity used for testing and calculation was a built-in lithium-on battery for a mobile phone, and some of its parameters are shown in Table 1 below.

TABLE 1
Partial Parameters of the Lithium Battery

| Parameter Name | Value | |
|---|---|---|
| Rated Capacity | 3130 | mAh |
| Rated Voltage | 3.85 | V |
| Constant-Current Charging Cut-off Voltage | 4.4 | V |
| End-of-Charge Current | 0.1 | A |
| End-of-Discharge Voltage | 2.45 | V |

A test including 400 charge-discharge cycles was conducted on the lithium-on battery with a depth of discharge (DOD) of 0% to 100% at room temperature. The charge and discharge data were recorded using both a battery cycler and a fuel gauge to represent the true SOH values of the battery. The following sections provide a comparison between the true SOH values, the SOH values estimated based on the FCC database 803 without Kalman filtering, and the SOH values estimated based on the FCC database 803 with Kalman filtering.

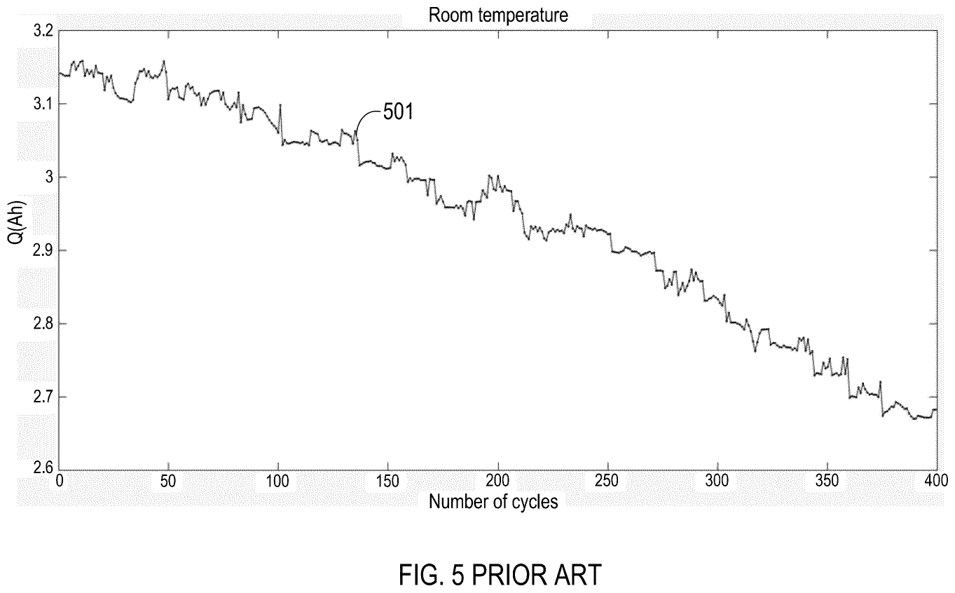

FIG. 5 illustrates an example of a capacity degradation curve 501 of the lithium battery described by Table 1, recorded by a battery cycler over 400 charge-discharge cycles at a depth of discharge (DOD) of 0% to 100% at room temperature, according to the prior art. As indicated by the capacity decay curve 501, the battery capacity Q(Ah) follows a downward trend as the number of charge-discharge cycles increases. Fluctuations in the capacity curve, e.g., the “burr-like” jittery portions in the figure, are caused by changes in external ambient temperature and periodic capacity regeneration phenomena.

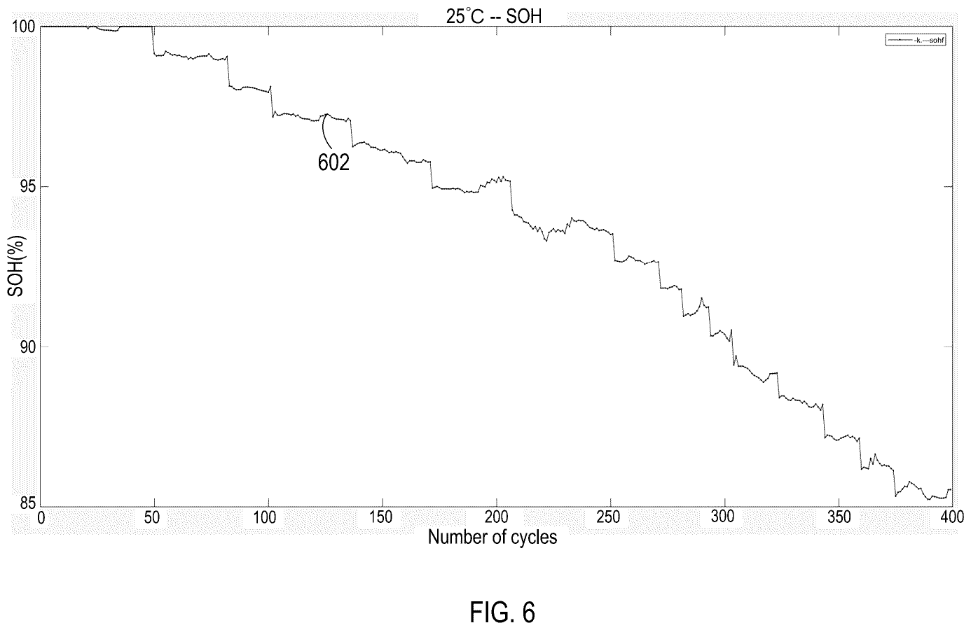

FIG. 6 illustrates an example of a curve 602 of SOH estimated values sohs of the lithium battery described by Table 1, determined based on an FCC database, e.g., 803, without Kalman filtering, in an embodiment of the present disclosure.

Although the SOH estimated values soh_{f} shown in FIG. 6 still exhibit some curve jitter with a maximum difference of 0.85%, the magnitude of these fluctuations is significantly reduced compared to the true battery SOH values corresponding to the capacity decay curve 501 recorded by the cycler in FIG. 5. Consequently, the battery SOH estimated values soh_{f} according to an embodiment of the present disclosure provide a more stable SOH estimation output, thereby enhancing the user experience.

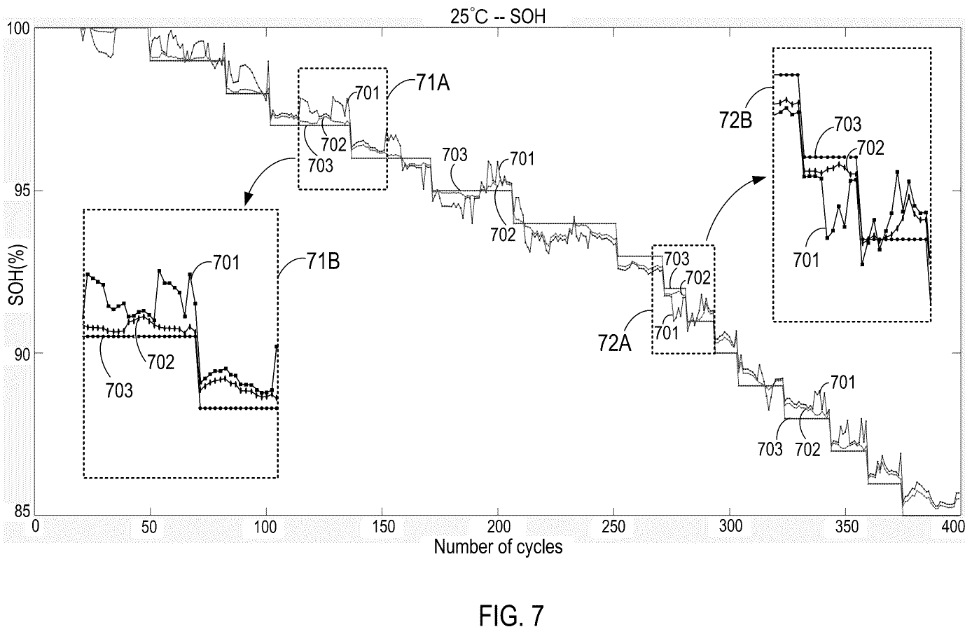

FIG. 7 illustrates a comparison between an SOH curve 701 determined by a cycler, an SOH curve 702 determined based on an FCC database, e.g., 803, without Kalman filtering, and an SOH curve 703 determined based on the FCC database with Kalman filtering, in an embodiment of the present disclosure. More specifically, in FIG. 7, curve 701 represents the true SOH values of the lithium-on battery recorded by the cycler; curve 702 represents the SOH estimated values soh_{f} of the lithium-on battery determined based on the FCC database; and curve 703 represents the filtered SOH values of the sohs using Kalman filtering. To better distinguish between curves 701, 702, and 703, FIG. 7 also provides an enlarged view 71B of the curves within box 71A and an enlarged view 72B of the curves within box 72A.

In some embodiments, a true SOH value of a battery after each charge-discharge cycle is calculated as follows:

$${SOH\_true}_{i} = \frac{{fcc}_{i}}{{fcc}_{1} * 100 \%} , \qquad ( 13 )$$

where fcc₁ represents the battery capacity recorded by a cycler at (or right after) the first charge-discharge cycle (at which point the initial battery SOH is 100%), and fccᵢ represents the battery capacity recorded by the cycler at (or right after) the i^{th} charge-discharge cycle.

According to the example of FIG. 7, the differences between the SOH estimated values soh_{f} determined based on the FCC database (e.g., represented by curve 702) and the true SOH values recorded by the cycler (e.g., represented by curve 701) are within 2%, with a maximum error of 1.05%. At (or right after) the 400^{th} charge-discharge cycle, the filtered SOH value of the soh_{f} using Kalman filtering is 85%, while the true SOH value is 85.72%, resulting in a relatively small difference, 0.72%.

Battery capacity varies due to factors such as changes in external ambient temperature or periodic capacity regeneration phenomena. Because the true SOH values of the lithium-on battery are calculated using capacity ratios, these capacity variations cause the true SOH values to fluctuate. However, the state equation of the Kalman filter suppresses these sharp increases and decreases in capacity, presenting a steady downward trend for the SOH value.

As shown in FIG. 7, the SOH estimated values sohs without Kalman filtering (e.g., represented by curve 702) already provide more stable results with high accuracy compared to the true values (e.g., represented by curve 701). Performing Kalman filtering on the SOH estimated values soh_{f} provides even more stable and effective results. By integrating Kalman filtering into the adaptive fusion SOH estimation algorithm, instances where the SOH abruptly increases or drops as cycle counts rise are suppressed. This can effectively reduce output noise during abnormal conditions, such as over-temperature or under-temperature, leading to better stability throughout the entire lifecycle while meeting the required accuracy for SOH estimation.

### Apparatus Embodiment

FIG. 8 illustrates a block diagram of an example of an apparatus 800 configured to determine an SOH of a battery 810, in an embodiment of the present disclosure. FIG. 8 is described in combination with FIG. 1, FIG. 2, FIG. 3, FIG. 4, and FIG. 9.

As shown in FIG. 8, the apparatus 800 includes a processing circuit 801, an acquisition circuit 802, and a memory 805 (e.g., a non-transitory computer storage medium). The memory 805 is configured to store a battery FCC database 803 and computer-executable instructions 804. When the computer-executable instructions 804 are executed by the processing circuit 801, the processing circuit 801 can update the FCC database 803 based on charging data 812 collected/acquired from the battery 810 during a charging process. The FCC database 803 is configured to record battery capacity estimation data 92 corresponding to reference values 91 for a group of detected quantities 811 in the battery charging process. When the filling of the FCC database 803 is determined to be completed through the updates, the SOH of the battery is calculated based at least on the FCC database 803. In some embodiments, the apparatus 800 can also include an acquisition circuit 802 configured to acquire/collect the charging data 812 during the battery charging process. The acquisition circuit 802 may be implemented, for example, as a sensor or a detection circuit for measuring various detected quantities 811 of the battery.

The processes and functions implemented by the processing circuit 801 have been described in the first through third method embodiments above. Therefore, a summary of the functions of the processing circuit 801 is provided below without repeating certain details already presented. In some embodiments, the processing circuit 801 may be implemented, for example, as a chip, a processor, or a microcontroller, and may be realized by one or more application-specific integrated circuits (ASICs) and/or corresponding software programs.

In some embodiments, the processing circuit 801 is configured to: determine a value for each of a group of detected quantities 811 during a battery charging process based on charging data 812; perform multi-dimensional linear interpolation on battery capacity estimation data 92 based on a comparison between the value of each detected quantity and a corresponding reference value to determine a cumulative capacity value CP_{CM}; and update the battery capacity estimation data 92 based on the cumulative capacity value CP_{CM} and an estimated charge amount fcc_est_{c} derived from the charging data 812.

In some embodiments, the processing circuit 801 is further configured to: for each detected quantity 811, determine one or more sets of nearest-neighbor reference values 91 (e.g., by identifying the abovementioned nearest-neighbor data points); determine a weight WGT for the battery capacity estimation data 92 corresponding to each reference value 91 based on the difference between the value of the detected quantity 811 and the reference value 91; and calculate a weighted sum of the estimated battery capacity values 922 in the battery capacity estimation data 92 corresponding to the one or more sets of nearest-neighbor reference values 91 as the cumulative capacity value CP_{CM}, thereby performing the multi-dimensional linear interpolation.

In some embodiments, the processing circuit 801 is further configured to: calculate the difference between the estimated charge amount fcc_est_{c} from the charging data 812 and the cumulative capacity value CP_{CM} as a capacity error value fcc_error; and update the estimated battery capacity values 922 and update counts 923 respectively corresponding to the one or more sets of nearest-neighbor reference values 91 based on the capacity error value fcc_error and the weight WGT.

In some embodiments, the processing circuit 801 is further configured to: update the initial battery capacity value 921 when the update count 923 equals a preset threshold, e.g., update_th1.

In some embodiments, the processing circuit 801 is further configured to: determine the estimated charge amount fcc_est_{c} by summing a cumulative coulombic charge CC during the battery charging process, a remaining capacity at the beginning of charging, and a capacity correction value associated with a termination current (or an end-of-charge current).

In some embodiments, the processing circuit 801 is further configured to: if the filling of the FCC database 803 is determined to be not completed, calculate the battery SOH based on a predetermined battery health aging factor dropratio and the number of charging cycles chg_cycle_cnt.

In some embodiments, the processing circuit 801 is further configured to: if the filling of the FCC database 803 is determined to be completed, calculate the battery SOH based on the ratio of the estimated battery capacity value 922 to the initial battery capacity value 921, from the battery capacity estimation data 92 with the highest update count 923.

In some embodiments, the processing circuit 801 is further configured to: perform Kalman filtering on the calculated battery SOH, and output the filtered SOH as the final battery SOH value.

Basic principles of the present disclosure are described above in conjunction with specific embodiments. However, those skilled in the art can understand that all or any steps or components of the methods and apparatuses of the present disclosure may be implemented in any computing device (including processors, storage media, and the like) or a network of computing devices, in a form of hardware, firmware, software or a combination thereof. Such implementation can be realized by those skilled in the art after reading the description of the present disclosure, by utilizing basic knowledge of circuit design or basic programming skills.

Moreover, a programmable product storing machine-readable instruction code is further provided according to an embodiment of the present disclosure. The instruction codes, when read and executed by a machine, can implement the method according to any of the embodiments of the present disclosure.

Accordingly, a storage medium for carrying the programmable product storing the machine-readable instruction codes is further included in the present disclosure. The storage medium includes, but is not limited to, a floppy disk, an optical disk, a magneto-optical disk, a storage card, a memory stick, and the like. In a case of implementing the embodiments of the present disclosure in software or firmware, a programmable product that includes the software is installed in a computer with a dedicated hardware structure from the storage medium or a network. The computer, when loaded with the various programs, performs various functions.

Components or steps in the method, apparatus and system of the present disclosure may be decomposed and/or recombined. Such decomposition and/or recombination should be considered as equivalents of the present disclosure. Furthermore, steps for executing the above processes may naturally be executed in a chronological order as described, but do not necessarily need to be executed in the chronological order. Certain steps may be performed in parallel with or independently of each other.

Finally, the terms “include,” “comprise” or any other variants thereof are intended to be non-exclusive. Therefore, a process, method, article, or device including a series of elements or components includes not only those elements/components but also includes, or may include, other elements/components that are not enumerated, or further includes elements/components inherent to the process, method, article, or device. In addition, unless expressly stated otherwise, the statement “comprising (including) a (n) . . . ” does not exclude the existence or presence of other identical or equivalent elements in the process, method, article or device.

The following configurations are provided in the present disclosure.
1. A method for determining a state of health (SOH) of a battery 810, the method comprising: updating, using a processing circuit 801, a full-charge-capacity (FCC) database based 803 on charging data 812 acquired during a charging process, wherein the FCC database 803 is configured to record battery capacity estimation data 92 corresponding to reference values 91 for a plurality of detected quantities 811 detected in the charging process; and in response to filling of the FCC database being determined to be completed through the updating, calculating the SOH of the battery based at least on the FCC database 803.
2. The method according to configuration 1, wherein the FCC database 803 comprises a plurality of data points 90-1 to 90-Y, wherein each data point of the plurality of data points 90-1 to 90-Y is configured to record respective battery capacity estimation data 92 associated with a respective set of reference values 91 for the detected quantities 811, and wherein the respective battery capacity estimation data 92 comprises an initial battery capacity value 921, an estimated battery capacity value 922, and an update count 923.
3. The method according to configuration 2, wherein the calculating of the SOH of the battery 810 based at least on the FCC database 803 comprises: if the filling of the FCC database 803 is determined to be completed, calculating the SOH of the battery 810 based on a ratio of an estimated battery capacity value 922 to an initial battery capacity value 921 at a data point having the highest update count among the plurality of data points 90-1 to 90-Y, thereby generating a calculated value soh_{f} of the SOH of the battery 810 (e.g., see the example of equation (11)).
4. The method according to configuration 3, further comprising: performing Kalman filtering on the calculated value soh_{f} of the SOH of the battery.
5. The method according to configuration 4, wherein the Kalman filtering is performed based on the abovementioned examples of state equation (1) and observation equation (2)
6. The method according to any of configurations 2-5, wherein if a data point of the plurality of data points 90-1 to 90-Y comprises an update count 923 that exceeds a preset threshold update_th2, and the initial battery capacity value 921 and the estimated battery capacity value 922 at the data point are greater than zero, the filling of the FCC database 803 is determined to be completed.
7. The method according to any of configurations 2-6, wherein the updating of the FCC database 803 comprises: determining a value of a detected quantity (e.g., an average temperature tempₐᵥₑᵣ and/or a maximum current curr_{MAX}) of the plurality of detected quantities 811 based on the charging data 812; identifying, in the FCC database 803, one or more nearest-neighbor data points (e.g., the four nearest-neighbor data points mentioned in relation to step S3123 in FIG. 4) comprising a nearest-neighbor reference value of the value of the detected quantity (e.g., the abovementioned reference values temp₀ and temp₁ of the average temperature tempₐᵥₑᵣ, and/or the reference values curr₀ and curr₁ of the maximum current curr_{MAX}); performing linear interpolation using the nearest-neighbor data points to determine a cumulative capacity value CP_{CM} (e.g., see the example of step S3124 in FIG. 4); and updating battery capacity estimation data 92 in each data point of the nearest-neighbor data points based on the cumulative capacity value CP_{CM} and an estimated charge amount fcc_est_{c} from the charging data 812.
8. The method according to configuration 7, wherein the performing linear interpolation comprises: determining a weight (e.g., temp_weight₀, temp_weight₁, curr_weight₀, or curr_weight₁) of an estimated battery capacity value (e.g., fcc_est_{tempi,currj}; i,j∈{0, 1}) in the nearest-neighbor data points based on a difference between the value of the detected quantity and the nearest-neighbor reference value (e.g., see the examples of equations (3) to (6)); and calculating a weighted sum of estimated battery capacity values in the plurality of nearest-neighbor data points as the cumulative capacity value CP_{CM} (e.g., see the example of equation (7))
9. The method according to configuration 8, wherein the updating of battery capacity estimation data 92 comprises: calculating a difference between the estimated charge amount fcc_est_{c} and the cumulative capacity value CP_{CM} as a capacity error value fcc_error (e.g., see the example of equation (8)); and updating the estimated battery capacity value (e.g., fcc_est_{tempi,currj}) in each data point of the nearest-neighbor data points based on the capacity error value fcc_error and a corresponding weight (e.g., temp_weightᵢ and curr_weightⱼ; see the example of equation (10)); and updating the update count 923 in each data point of the nearest-neighbor data points, e.g., by incrementing it by one.
10. The method according to any of configurations claim 7-9, wherein the updating of the FCC database 803 further comprises: if an update count 923 of a data point of the nearest-neighbor data points is equal to a preset threshold update_th1, updating an initial battery capacity value 921 in that data point to the estimated battery capacity value (e.g., fcc_est_{tempi,currj}), in the data point, that is updated using linear interpolation.
11. The method according to any of configurations 1-10, wherein the charging data 812 comprises at least one parameter of parameters comprising: a maximum temperature value, a minimum temperature value, a maximum current value, a minimum current value, a coulombic accumulation amount, a state of charge (SOC) at a beginning of the charging process, an SOC at an end of the charging process, and an estimated charge amount fcc_est_{c} for a present charging cycle.
12. The method according to configuration 11, wherein the estimated charge amount fcc_est_{c} is calculated as a sum of a cumulative coulombic charge CC in the charging process, a remaining capacity at the beginning of the charging process, and a capacity correction value associated with a termination current (e.g., see the example of equation (9)).
13. The method according to any of configurations 1-12, further comprising: if the filling of the FCC database 803 is determined to be not completed, calculating the SOH of the battery 810 according to a predetermined aging factor dropratio of a battery health value and the number of charging cycles chg_cycle_cnt the battery 810 experienced (e.g., see the example of equation (12)).
14. The method according to any of configurations 1-13, wherein the plurality of detected quantities 811 comprises current and temperature.
15. The method according to configuration 14, wherein the current comprises a maximum current value curr_{MAX} of the battery 810 in the charging process, and the temperature comprises an average temperature value tempₐᵥₑᵣ of the battery 810 in the charging process.
16. An apparatus 800 operable for determining an SOH of a battery 801, the apparatus 800 comprising: an acquisition circuit 802 configured to acquire charging data 812 of the battery 810 during a charging process; and a processing circuit 801, coupled to the acquisition circuit 802, and configured to update an FCC database 803 based on the charging data 812, wherein the FCC database 803 is configured to record battery capacity estimation data 92 corresponding to reference values 91 for a plurality of detected quantities 811 detected in the charging process, and wherein the processing circuit 801 is configured to calculate the SOH of the battery 810 based at least on the FCC database 803 in response to filling of the FCC database 803 being determined to be completed.
17. The apparatus 800 according to configuration 16, wherein the FCC database 803 comprises a plurality of data points 90-1 to 90-Y, wherein each data point of the plurality of data points 90-1 to 90-Y is configured to record respective battery capacity estimation data 92 associated with a respective set of reference values 91 for the detected quantities 811, and wherein the respective battery capacity estimation data 92 comprises an initial battery capacity value 921, an estimated battery capacity value 922, and an update count 923.
18. The apparatus according to configuration 17, wherein the processing circuit 801 is configured to update the FCC database 803 by performing a plurality of operations comprising: determining a value of a detected quantity (e.g., an average temperature tempₐᵥₑᵣ and/or a maximum current curr_{MAX}) of the plurality of detected quantities 811 based on the charging data 812; identifying, in the FCC database 803, one or more nearest-neighbor data points (e.g., the four nearest-neighbor data points mentioned in relation to step S3123 in FIG. 4) comprising a nearest-neighbor reference value of the value of the detected quantity (e.g., the abovementioned reference values temp₀ and temp₁ of the average temperature tempₐᵥₑᵣ, and/or the reference values curr₀ and curr₁ of the maximum current curr_{MAX}); performing linear interpolation using the nearest-neighbor data points to determine a cumulative capacity value CP_{CM} (e.g., see the example of step S3124 in FIG. 4); and updating battery capacity estimation data 92 in each data point of the nearest-neighbor data points based on the cumulative capacity value CP_{CM} and an estimated charge amount fcc_est_{c} from the charging data 812.
19. The apparatus according to any of configurations 17 and 18, wherein if the filling of the FCC database 803 is determined to be completed, then the processing circuit 801 is configured to calculate the SOH of the battery 810 based on a ratio of an estimated battery capacity value 922 to an initial battery capacity value 921 at a data point having the highest update count among the plurality of data points 90-1 to 90-Y, thereby generating a calculated value soh_{f} of the SOH of the battery 810 (e.g., see the example of equation (11)).
20. The apparatus according to configuration 19, wherein the processing circuit 801 is further configured to perform Kalman filtering on the calculated value soh_{f} of the SOH of the battery.

Although the embodiments of the present disclosure are described in detail above with reference to the accompanying drawings, the embodiments are only for illustrating the present disclosure and do not constitute a limitation of the present disclosure. For those skilled in the art, various modifications and changes can be made to the embodiments without departing from the spirit and scope of the present disclosure. Therefore, the scope of the present disclosure is limited only by the appended claims and equivalents thereof.

What is claimed is:

1. A method for determining a state of health (SOH) of a battery, said method comprising:
updating, using a processing circuit, a full-charge-capacity (FCC) database based on charging data acquired during a charging process, wherein said FCC database is configured to record battery capacity estimation data corresponding to reference values for a plurality of detected quantities detected in said charging process; and
in response to filling of said FCC database being determined to be completed through said updating, calculating said SOH of said battery based at least on said FCC database.

2. The method according to claim 1, wherein said FCC database comprises a plurality of data points,
wherein each data point of said plurality of data points is configured to record respective battery capacity estimation data associated with a respective set of reference values for said detected quantities,
and wherein said respective battery capacity estimation data comprises an initial battery capacity value, an estimated battery capacity value, and an update count.

3. The method according to claim 2, wherein said calculating said SOH of said battery based at least on said FCC database comprises:
if said filling of said FCC database is determined to be completed, then calculating said SOH of said battery based on a ratio of an estimated battery capacity value to an initial battery capacity value at a data point having a highest update count among said plurality of data points, thereby generating a calculated value of said SOH of said battery.

4. The method according to claim 3, further comprising:
performing Kalman filtering on said calculated value of said SOH of said battery.

5. The method according to claim 4, wherein in said Kalman filtering, system noise and measurement noise of a Kalman filter equation are dynamically adjusted according to temperature to construct a state equation and an observation equation, wherein:
said state equation is given by: sohₖ=sohₖ₋₁−dropratio/10+w; and
said observation equation is given by: sohₖ=soh_{f}+v,
where sohₖ represents a value of said SOH of said battery in a k^{th} iteration; sohₖ₋₁ represents a value of said SOH of said battery at a (k−1)^{th} iteration; soh_{f} represents said calculated value of said SOH of said battery; dropratio represents a predetermined aging factor of said battery; w represents said system noise; and v represents said measurement noise.

6. The method according to claim 2, wherein if a data point of said plurality of data points comprises an update count that exceeds a preset threshold, and an initial battery capacity value and an estimated battery capacity value at said data point are greater than zero, then said filling of said FCC database is determined to be completed.

7. The method according to claim 2, wherein said updating of said FCC database comprises:
determining a value of a detected quantity of said plurality of detected quantities based on said charging data;
identifying, in said FCC database, at least one nearest-neighbor data point comprising a nearest-neighbor reference value of said value of said detected quantity;
using said at least one nearest-neighbor data point to determine a cumulative capacity value; and
updating battery capacity estimation data in each data point of said at least one nearest-neighbor data point based on said cumulative capacity value and an estimated charge amount from said charging data.

8. The method according to claim 7, wherein said at least one nearest-neighbor data point comprises a plurality of nearest-neighbor data points, and wherein said cumulative capacity value is determined by:
determining a weight of an estimated battery capacity value in said plurality of nearest-neighbor data points based on a difference between said value of said detected quantity and said nearest-neighbor reference value; and
calculating a weighted sum of estimated battery capacity values in said plurality of nearest-neighbor data points as said cumulative capacity value.

9. The method according to claim 8, wherein said updating battery capacity estimation data comprises:
calculating a difference between said estimated charge amount and said cumulative capacity value as a capacity error value; and
updating an estimated battery capacity value in said each data point of said at least one nearest-neighbor data point based on said capacity error value and a corresponding weight; and
updating an update count in said each data point of said at least one nearest-neighbor data point.

10. The method according to claim 7, wherein said updating of said FCC database further comprises:
if an update count of a data point of said least one nearest-neighbor data point is equal to a preset threshold, updating an initial battery capacity value in said data point to an estimated battery capacity value, in said data point.

11. The method according to claim 1, wherein said charging data comprises at least one parameter of parameters comprising: a maximum temperature value, a minimum temperature value, a maximum current value, a minimum current value, a coulombic accumulation amount, a state of charge (SOC) at a beginning of said charging process, an SOC at an end of said charging process, and an estimated charge amount for a present charging cycle.

12. The method according to claim 11, wherein said estimated charge amount is calculated as a sum of a cumulative coulombic charge in said charging process, a remaining capacity at said beginning of said charging process, and a capacity correction value associated with a termination current.

13. The method according to claim 1, further comprising:
if said filling of said FCC database is determined to be not completed, calculating said SOH of said battery according to a predetermined aging factor of a battery health value and a number of charging cycles said battery experienced.

14. The method according to claim 1, wherein said plurality of detected quantities comprises current and temperature.

15. The method according to claim 14, wherein said current comprises a maximum current value of said battery in said charging process, and said temperature comprises an average temperature value of said battery in said charging process.

16. An apparatus operable for determining a state of health (SOH) of a battery, said apparatus comprising:
an acquisition circuit configured to acquire charging data of said battery during a charging process; and
a processing circuit, coupled to said acquisition circuit, and configured to update a full-charge-capacity (FCC) database based on said charging data, wherein said FCC database is configured to record battery capacity estimation data corresponding to reference values for a plurality of detected quantities detected in said charging process, and wherein said processing circuit is further configured to calculate said SOH of said battery based at least on said FCC database in response to filling of said FCC database being determined to be completed.

17. The apparatus according to claim 16, wherein said FCC database comprises a plurality of data points,
wherein each data point of said plurality of data points is configured to record respective battery capacity estimation data associated with a respective set of reference values for said detected quantities,
and wherein said respective battery capacity estimation data comprises an initial battery capacity value, an estimated battery capacity value, and an update count.

18. The apparatus according to claim 17, wherein said processing circuit is configured to update said FCC database by performing a plurality of operations comprising:
determining a value of a detected quantity of said plurality of detected quantities based on said charging data;
identifying, in said FCC database, at least one nearest-neighbor data point comprising a nearest-neighbor reference value of said value of said detected quantity;
using said at least one nearest-neighbor data point to determine a cumulative capacity value; and
updating battery capacity estimation data in each data point of said at least one nearest-neighbor data point based on said cumulative capacity value and an estimated charge amount from said charging data.

19. The apparatus according to claim 17, wherein if said filling of said FCC database is determined to be completed, then said processing circuit is configured to calculate said SOH of said battery based on a ratio of an estimated battery capacity value to an initial battery capacity value at a data point having a highest update count among said plurality of data points, thereby generating a calculated value of said SOH of said battery.

20. The apparatus according to claim 19, wherein said processing circuit is further configured to perform Kalman filtering on said calculated value of said SOH of said battery.
